(19) United States
(12) Patent Application Publication
(10) Pub. No.: US 2010/0090254 A1
(43) Pub. Date: Apr. 15, 2010

(54) BIOSENSOR AND MANUFACTURING METHOD THEREOF

(75) Inventors: Chang-Geun Ahn, Daejon (KR); Seongjae Lee, Seoul (KR); Jong-Heon Yang, Daejon (KR); In-Bok Baek, Chungbuk (KR); Han-Young Yu, Daejon (KR); Chil-Seong Ah, Daejon (KR); Ansoon Kim, Daejon (KR); Chan-Woo Park, Daejon (KR); Seon-Hee Park, Daejon (KR); Taehyoung Zyung, Daejon (KR)

Correspondence Address: AMPACC Law Group, 3500 188th Street S.W., Suite 103, Lynnwood, WA, 98037, US

(73) Assignee: Electronics and Telecommunications Research Institute, Daejon (KR)

(21) Appl. No.: 12/517,553

(22) PCT Filed: Nov. 22, 2007
(86) PCT No.: PCT/KR07/05908

§ 371 Date: Jun. 3, 2009

(30) Foreign Application Priority Data
Dec. 4, 2006 (KR) 10-2006-0121624
Jul. 2, 2007 (KR) 10-2007-00066125

(51) Int. Cl. H01L 29/66; H01L 21/04

(52) U.S. Cl. 257/253; 438/49; 257/E29.166; 257/E21.04

(57) ABSTRACT

Provided is a biosensor which can detect a specific biomaterial by an interaction between target molecules and probe molecules, and a manufacturing method thereof. The biosensor includes: a first conductive semiconductor substrate; a second conductive doping layer formed on the semiconductor substrate; an electrode formed on top of both opposite ends of the doping layer; and probe molecules immobilized on the doping layer.

### TECHNICAL FIELD

The present invention relates to a biosensor and a manufacturing method thereof; and more particularly, to a biosensor which can detect a specific biomaterial by an interaction between target molecules and probe molecules, and a manufacturing method thereof.

This work was supported by the IT R&D program of MIC/IITA [2006-S-007-01, “Ubiquitous Health Monitoring Module and System Development”].

### BACKGROUND ART

Recently, many efforts are being rapidly made based on the Biology Technology (BT) to develop a new technical foundation by converging Information Technology (IT) and Nano Technology (NT), which have been developed independently. Especially, researchers have studied biosensors aiming to detect proteins in blood in the nano-biochip field, which is one of the Nano-Bio (NT-BT) merging techniques.

In the nano-biochip field, various methods for detection, analysis, and quantification of a specific biomaterial have been developed. Among them is a method of detecting a specific biomaterial by fluorescence labeling. The fluorescence labeling method is frequently applied to a DNA chip that is currently available.

However, the fluorescence labeling method requires an additional biochemical preparation step of preparing measurement samples, such as blood and saliva, in order to detect a specific biomaterial. This makes it difficult to apply various materials. For example, in the labeling of proteins, about 50% of the functional protein can be inactivated in the procedure of nonspecific labeling. Therefore, there is a drawback that only very small quantities of the analyte are available for purposes.

Consequently, silicon-based biosensors using a semiconductor process while improving sensitivity or reproducibility have been proposed and this is suitable for mass production. In one example, a biosensor capable of detecting a specific biomaterial by using silicon nanowires has been suggested.

The biosensor using silicon nanowires provides a great sensitivity since it can sense a change with high sensitivity, which is caused by an interaction between target molecules and probe molecules, for example, a change in conductivity. However, it is not easy to synthesize nanowires, and it is difficult to align the nanowires at desired position in the biosensor. This makes it difficult to manufacture a biosensor using nanowires.

To solve this problem, recently proposed is a technique of manufacturing a biosensor having a sensitive nanostructure for detecting a specific biomaterial which is based on a Silicon On Insulator (SOI) substrate and patterns nanowires in a top-down way by using the standard semiconductor process techniques.

However, the biosensor using such an SOI substrate has the problem that the sensitivity of the biosensor is lowered due to a trap on or near the surface of a Buried Oxide Layer (BOX) contacting an upper silicon layer on which the nanowires of the SOI substrate are formed. Further, the sensor using an expensive SOI substrate has an inherent major problem of very high manufacturing cost.

### DISCLOSURE OF INVENTION

### Technical Problem

It is, therefore, an object of the present invention to provide a biosensor which can be manufactured at a low cost, and a manufacturing method thereof.

It is another object of the present invention to provide a biosensor with an improved sensitivity, and a manufacturing method thereof.

It is yet another object of the present invention to provide a biosensor which can detect a plurality of specific biomaterials within one biosensor, and a manufacturing method thereof.

Other objects and advantages of the present invention can be understood by the following description, and become apparent with reference to the embodiments of the present invention. Also, it is obvious to those skilled in the art of the present invention that the objects and advantages of the present invention can be realized by the means as claimed and combinations thereof.

### Technical Solution

In accordance with an aspect of the present invention, there is provided a biosensor, which includes: a first conductive semiconductor substrate; a second conductive doping layer formed on the semiconductor substrate; an electrode formed on top of both opposite ends of the doping layer; and probe molecules immobilized on the doping layer. The semiconductor substrate and the doping layer may be electrically separated from each other by junction isolation.

The doping layer may be an epitaxial layer, which is an ion implantation layer or a diffusion layer. The doping layer may be provided in plural, each doping layer having a different probe molecule immobilized thereon.

The biosensor may further include a fluid tube for providing a fluid path in a region of the doping layer on which the probe molecules are immobilized. The probe molecules may be formed of any one selected from the group consisting of antigens, antibodies, DNA, proteins and a combination thereof.

In accordance with another aspect of the present invention, there is provided a method for manufacturing a biosensor, which includes the steps of: a) forming a second conductive doping layer on a first conductive semiconductor substrate; b) forming an electrode on top of both opposite ends of the doping layer; and c) immobilizing probe molecules on the doping layer. The semiconductor substrate and the doping layer may be N-type and P-type or P-type and N-type, respectively, to complement each other, and electrically separated from each other by junction isolation.

The doping layer may be formed by growing an epitaxial layer on top of the semiconductor layer and doping impurities simultaneously through in-situ method. The doping layer may be formed on the surface of the semiconductor substrate by using an ion implantation method or a thermal diffusion method. The method may further include the step of forming a channel region and a pad region by patterning the doping layer.

The method may further include the step of forming a fluid tube for providing a fluid path in a region of the doping layer on which the probe molecules are immobilized. The probe molecules may be formed of any one selected from the group consisting of antigens, antibodies, DNA, proteins, and a combination thereof.

### ADVANTAGEOUS EFFECTS

As mentioned above and will be discussed below, the present invention can produce a biosensor at a low cost by manufacturing a biosensor using a cheap bulk silicon substrate instead of an expensive SOI substrate by junction isolation.

In addition, the present invention can improve the sensitivity of the biosensor by fundamentally preventing the lowering of the sensitivity caused by a trap on the SOI substrate by electrically separating the substrate and sensitive regions by junction isolation.

Further, the present invention makes it easier to quantify measurement values of the biosensor and acquire the reproducibility thereof by forming a doping layer so as to have a uniform doping profile in vertical and horizontal directions.

Furthermore, the present invention can improve the sensitive property of the biosensor by freely adjusting the shape of channel areas.

Moreover, the present invention can detect a plurality of specific biomaterials in one biosensor by employing a plurality of doping layers with different probe molecules immobilized thereon.

### BRIEF DESCRIPTION OF THE DRAWINGS

FIG. 1 is a perspective view showing a biosensor in accordance with an embodiment of the present invention.

FIG. 2 is a cross-sectional view taken along a line X-X′ of FIG. 1.

FIG. 3 is a schematic view explaining junction isolation between a semiconductor substrate and a doping layer in accordance with the present invention.

FIG. 4 is a current-voltage characteristic graph showing Iₜₒₚ and I_{sub} as illustrated in FIG. 3.

FIG. 5 is a schematic view explaining the operation principle of the biosensor in accordance with an embodiment of the present invention.

FIGS. 6 to 11 are cross-sectional views describing a method for manufacturing a biosensor in accordance with another embodiment of the present invention.

### BEST MODE FOR CARRYING OUT THE INVENTION

The advantages, features and aspects of the invention will become apparent from the following description of the embodiments with reference to the accompanying drawings, which is set forth hereinafter.

Hereinafter, embodiments of the present invention will be set forth in detail with reference to the accompanying drawings so that the invention can easily be carried out by those skilled in the art.

In the drawings, the thickness of layers and regions is exaggerated for clarity. It will also be understood that when a layer is referred to as being on another layer or substrate, it can be directly formed on another layer or substrate or a third layer may be interposed therebetween. The same reference numerals are denoted for the same elements throughout the specification.

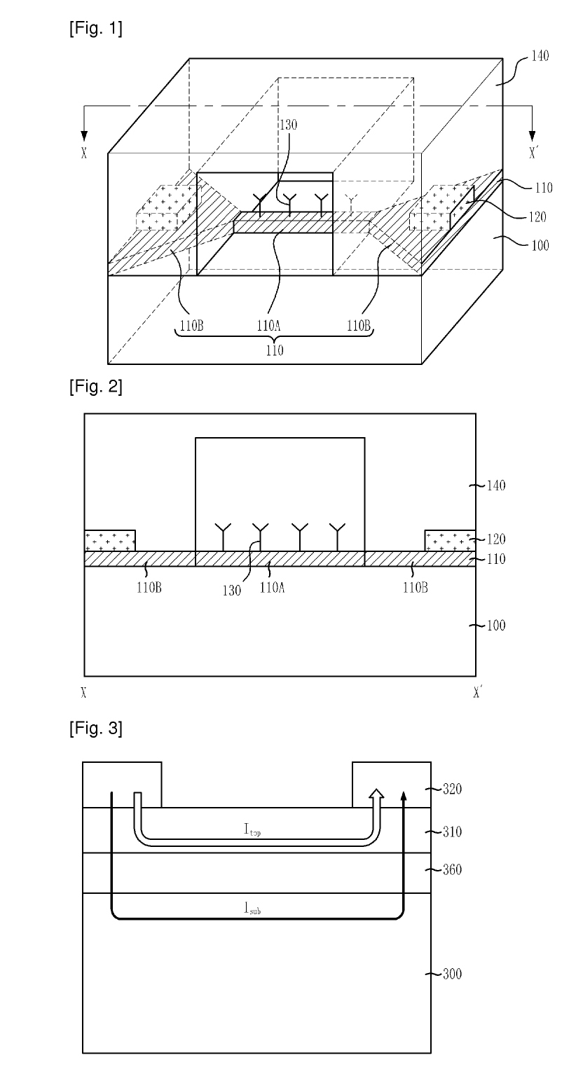

FIG. 1 and FIG. 2 are views showing a biosensor in accordance with an embodiment of the present invention. FIG. 1 is a perspective view, and FIG. 2 is a cross-sectional view taken along a line X-X′ of FIG. 1.

As shown in FIGS. 1 and 2, the biosensor of the present invention includes a first conductive semiconductor substrate 100, a second conductive doping layer 110 formed on the semiconductor substrate 100, an electrode 120 formed on top of both opposite ends of the doping layer 110, probe molecules 130 immobilized on the doping layer 110, and a fluid tube 140 for providing a fluid path in the region of the doping layer 110 on which the probe molecules 130 are immobilized. The semiconductor substrate 100 may be a cheap bulk silicon substrate.

The doping layer 110 may be formed in N-type or P-type to be complementary to the semiconductor substrate 100. To be specific, if the semiconductor substrate 100 is a P-type conductive substrate doped with boron (B) which is P-type impurity, the doping layer 110 is formed as an N-type conductive layer doped with phosphorous (P) which is N-type impurity. By doing so, the semiconductor 100 and the doping layer 110 can be electrically separated from each other by junction isolation. This will be described with reference to FIGS. 3 and 4.

FIG. 3 is a schematic view for explaining junction isolation between a semiconductor substrate and a doping layer in accordance with the present invention, and FIG. 4 is a current-voltage characteristic graph showing Iₜₒₚ and I_{sub} as illustrated in FIG. 3.

First, as shown in FIG. 3, a doping layer 310 doped with impurities of a type different from a silicon substrate 300 is formed on top of the silicon substrate 300, and an electrode 320 is formed on top of both opposite ends of the doping layer 310. The doping layer 310 roughly has a height of 50 nm, a width of 100 nm, and a length of 10 μm. The silicon substrate 300 is doped with N-type impurities, e.g., 1×10¹⁵/cm³ of phosphorous (P), and the doping layer 310 is doped with P-type impurities, e.g., 1×10¹⁸/cm³ of boron (B).

Here, as the silicon substrate 300 and the doping layer 310 form a PN junction, a depletion layer 360 is formed between the silicon substrate 300 and the doping layer 310. Most of the depletion layer 360 is formed on the silicon substrate 300 side due to a difference in doping concentration. As a result, the silicon substrate 300 and the doping layer 310 are junction-isolated by the depletion region 360, and thus electrically separated.

Next, as shown in FIG. 4, since the doping layer 310 is electrically separated from the silicon substrate 300, the current, i.e., Iₜₒₚ, flowing through the doping layer 310 shows a value that is about 1,000 times as large as the current, i.e., I_{sub}, flowing in the silicon substrate 300. Such a result means that the doping layer 310 is electrically well separated from the silicon substrate 300 by junction isolation. Thus, this may lead to the effect electrically equivalent to the separation of an upper silicon layer of an SOI substrate from a lower substrate layer by a Buried Oxide Layer (BOX).

In this way, the biosensor of the present invention can use a cheap bulk silicon substrate instead of an expensive SOI substrate by electrically separating the semiconductor substrate 100 and the doping layer 110 by junction isolation. As a result, the biosensor can be manufactured at a low cost.

Further, the present invention can fundamentally prevent the lowering of the sensitivity of the biosensor caused by a trap between the semiconductor substrate 100 and the doping layer 110 by electrically separating therebetween by junction isolation.

The doping layer 110 may be either a diffusion layer formed by impurity diffusion on the semiconductor substrate 100, or an ion implantation layer formed by impurity ion implantation, or an epitaxial layer formed by epitaxial growth. Especially, the epitaxial layer has a uniform doping profile in vertical and horizontal directions, thus making it easier to quantify measurement values of the biosensor and acquire the reproducibility thereof.

Additionally, the doping layer 110 can be divided into a channel region 110A and a pad region 110B. Probe molecules 130 for detecting specific biomaterials, i.e., target molecules, are immobilized on the channel region 110A, and an electrode 120 is formed on the pad region 110B. At this time, the channel region 110A of the doping layer 110 is a region for sensing a change in conductivity caused by an interaction between the probe molecules 130 and the target molecules, and can be manufactured in various shapes in order to improve sensing efficiency.

Accordingly, the width of the channel region 110A may range from several nm to hundreds of μm. However, if the width of the channel region 110A becomes greater, the sensitivity may be relatively lowered. Therefore, it is preferred to form the channel region 110A to have a narrow width like silicon nanowires in order to acquire an excellent sensing property. Further, the overall resistance can be adjusted by adjusting the length of the channel region 110A, and thus, the amount of current can be controlled.

The electrode 120 may be formed of any one selected from the group consisting of a doped polysilicon film, a metal film, a conductive metal nitride film, and a metal silicide film, and any material can be used as long as it can form an ohmic contact with the pad region 110B of the doping layer 110.

The probe molecules 130 may be formed of any one selected from the group consisting of DNA, antigens, antibodies, and proteins or a combination thereof depending on the target molecules desired to be detected.

Moreover, in the biosensor of the present invention, a plurality of doping layers 110 may be provided in one biosensor, and different probe molecule 130 may be immobilized on each doping layer 110. In other words, the biosensor of the present invention enables multiplexing detection in which a plurality of target molecules are simultaneously detected by forming in one biosensor, a plurality of doping layers 110 each having different probe molecules 130 immobilized thereon.

In the process of immobilizing the probe molecules 130 in the channel region 110A of the doping layer 110, when reverse bias is applied between the semiconductor substrate 100 and the channel region 110A of the doping layer 110, the semiconductor substrate 100 comes to have the same charge as the probe molecules 130 in the solution to thereby induce repulsive force. This suspends the reaction and only the channel, which is charged with reverse bias, can involve in an electrochemical reaction.

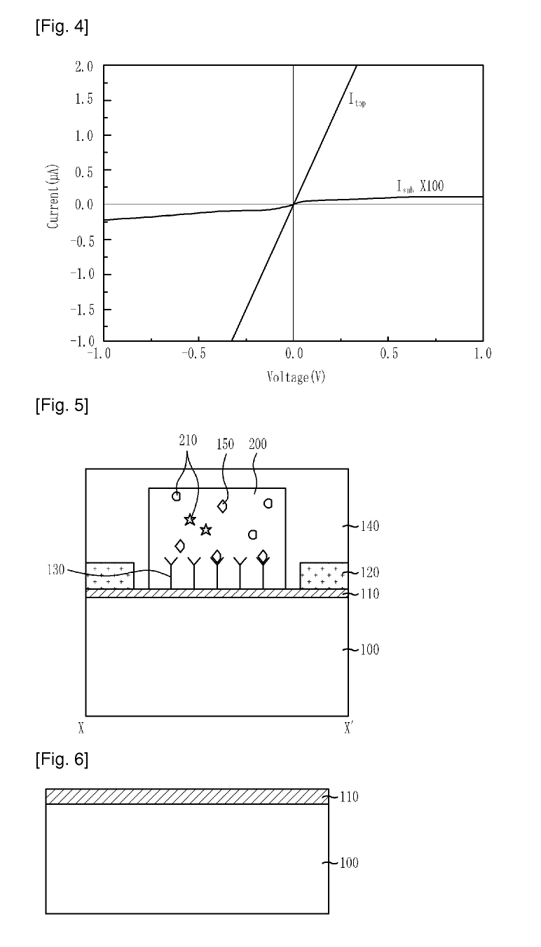

FIG. 5 is a schematic view for explaining the operating principle of the biosensor in accordance with the embodiment of the present invention.

As shown in FIG. 5, a measurement sample 200 is injected into the fluid tube 140 of the biosensor of the present invention. The measurement sample 200 may be in a gas or liquid state, and includes target molecules 150 reacting with the probe molecules 130 previously immobilized on the doping layer 110 and nonspecific molecules 210 not reacting with the probe molecules 130.

When the target molecules 150 in the injected measurement sample 200 are bound to the probe molecules 130 immobilized in the channel region 110A of the doping layer 110, the surface potential of the channel region 110A is changed, and subsequently, the change in the surface potential causes a change in a band structure.

This changes the distribution of electric charges in the channel region 110A to thus change the conductivity of the channel region 110A. Such a change in conductivity is linked to a specific processor capable of observing a change in conductivity through the electrode 120, thereby detecting the target molecules 150 within the measurement sample 200.

Hereinafter, an embodiment of a method for manufacturing a biosensor in accordance with the present invention will be described in detail with reference to the attached drawings. In the following description of the method, known technologies of the technical contents related to the manufacturing method of a semiconductor device or its related film formation method will not be described, and this means that the technical scope of the invention is not limited by such known technologies.

FIGS. 6 to 11 are process cross-sectional views showing a process for manufacturing a biosensor in accordance with the embodiment of the present invention.

As shown in FIG. 6, a doping layer 110 is formed on top of a semiconductor substrate 100. The semiconductor substrate 100 may be a cheap bulk silicon substrate, and the doping layer 110 is a layer having N-type or P-type complementary to the semiconductor substrate 100. For example, if the semiconductor substrate 100 is doped with P-type impurities, the doping layer 110 is a layer doped with N-type impurities and has a thickness ranging from 20 nm to 500 nm.

Here, the doping layer 110 may be formed in various methods by using a conventional, well-known semiconductor manufacturing technique. For instance, these methods include a method of forming the doping layer by thermal treatment after ion-implanting impurities on the surface of the semiconductor substrate 100 and a method of forming a doping layer by thermal diffusion of impurities on the surface of the semiconductor substrate 100.

The doping layer 110 may be formed in such a method of doping impurities in-situ while epitaxially growing the doping layer 110 on the semiconductor substrate 100 so as to have a uniform doping profile in vertical and horizontal directions. This is because, if the doping layer 110 has a uniform doping profile in vertical and horizontal directions, it is possible to quantify measurement values more accurately when sensing a change in conductivity caused by binding probe molecules 130 and target molecules 150, and make it easier to acquire the reproducibility of the biosensor.

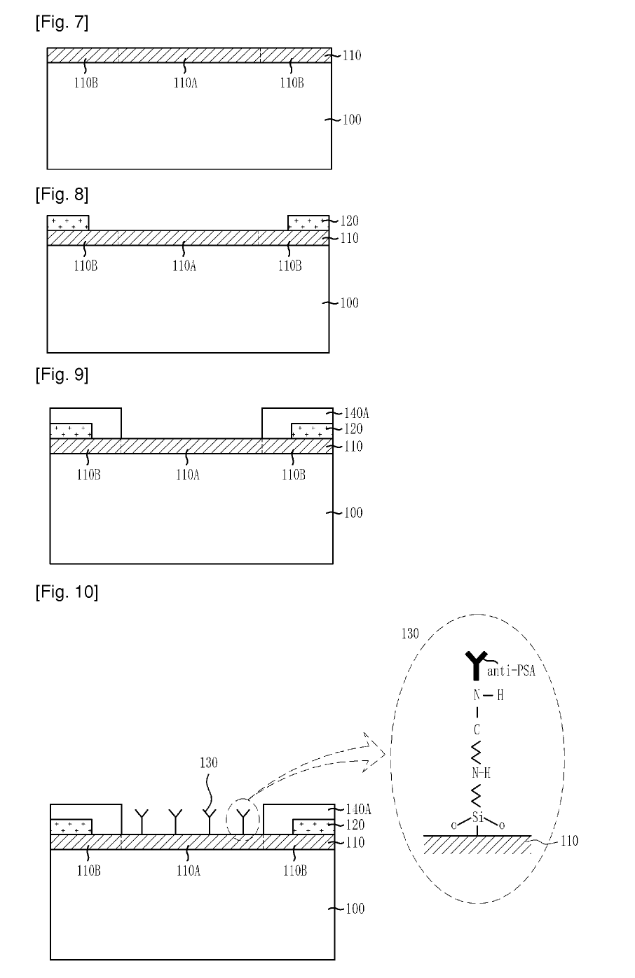

Next, as shown in FIG. 7, the doping layer 110 is formed of a channel region 110A and a pad region 110B through a mask process using formation of nanopattern and micropattern (refer to FIG. 1). At this time, the channel region 110A is a region having probe molecules immobilized therein through a subsequent process, for sensing a change in conductivity caused by an interaction between the probe molecules and target molecules.

Therefore, the channel region 110A may be formed in various shapes in order to sensitively sense a change in conductivity caused by an interaction between the probe molecules and the target molecules. Thus, the width of the channel region 110A may range from several nm to hundreds of μm.

However, if the width of the channel region 110A becomes greater, the sensitivity may be relatively lowered. Therefore, it is preferred to form the channel region 110A to have a narrow width like silicon nanowires in order to acquire an excellent sensing property. Further, the overall resistance can be adjusted by adjusting the length of the channel region 110A, and thus, the amount of current can be controlled.

Such a channel region 110A having a nanopattern may be formed by using any one of photolithography, electron beam lithography, ion-beam lithography, x-ray lithography, and a specific micropattern formation technique.

Next, as shown in FIG. 8, an electrode 120 is formed on top of the pad region 110B of the doping layer 110. The electrode 120 may be formed of any one selected from the group consisting of a doped polysilicon film, a metal film, a conductive metal nitride film, and a metal silicide film, and any material can be used as long as it can form an ohmic contact with the pad region 110B.

Thereafter, as shown in FIG. 9, an insulation film 140A is formed on top of the pad region 110B and the electrode 120. The insulation film 140A serves as a support for a fluid tube to be formed through a subsequent process and serves to electrically insulate the electrode 120 and the channel region 110A of the doping layer 110, and may be formed of a silicon oxide film SiO₂.

Next, as shown in FIG. 10, probe molecules 130 capable of detecting specific biomaterials, i.e., target molecules, are immobilized in the channel region 110A of the doping layer 110. The probe molecules 130 may be formed of any one selected from the group consisting of antigens, antibodies, DNA, and proteins or a combination thereof.

Hereinafter, a method of immobilizing the probe molecules 130 in the channel region 110A will be described in detail with reference to an enlarged view of the probe molecules 130. Here, an anti-Prostate Specific Antigens (PSA) immobilization method for detecting PSA will be described by way of example.

First, a hydroxyl functional group (—OH) is formed in the channel region 110A by O₂ plasma ashing. Then, an ethanol solution having 1% of aminopropyltriethoxy silane (APTES) dispersed therein is stirred, and the channel region 110A is dipped therein and then washed and dried. Subsequently, an aldehyde functional group (—CHO) is formed by using a 25 wt % glutaraldehyde solution. Lastly, the aldehyde functional group and anti-PSA are bound by using an anti-PSA solution, thus immobilizing the anti-PSA in the channel region 110A.

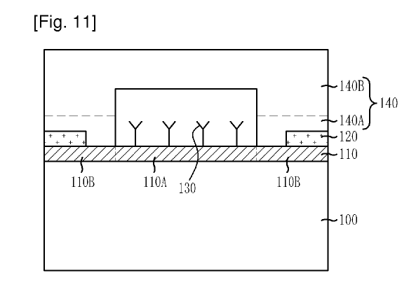

Finally, as shown in FIG. 11, a fluid tube 140 for providing a fluid path is formed in the channel region 110A of the doping layer 110. The fluid tube 140 may be formed in various methods by using a well-known technique. For instance, a polydimethylsiloane (PDMS) pattern 140B having a P-shape (with its bottom open) is formed by using PDMS, and then positioned on top of the semiconductor substrate 100. At this time, the P-shaped PDMS pattern 140B is aligned so that the lower face thereof is consistent with the top surface of the insulation film 140A, and then the semiconductor substrate 100 and the PDMS pattern 140B are tightly coupled, to thus form the fluid tube 140.

As mentioned above, it is possible to manufacture a biosensor capable of detecting one specific target material through the above-described process steps. Further, the biosensor of the present invention can detect a plurality of target molecules by forming a plurality of doping layers having different probe molecules immobilized thereon within one biosensor. That is, the biosensor of the present invention enables multiplexing detection by forming a plurality of doping layers each having different probe molecules within one biosensor.

After forming a plurality of doping layers in the process of forming a doping layer, in the process of immobilizing the probe molecules in the channel region of the doping layer, when reverse bias is applied between the semiconductor substrate 100 and the channel region 110A of the doping layer 110, the semiconductor substrate 100 comes to have the same charge as the probe molecules 130 in the solution to thereby induce repulsive force. This suspends the reaction and only the channel, which is charged with reverse bias, can involve in an electrochemical reaction. This immobilizes different probe molecules in the channel region of each doping layer.

The present application contains subject matter related to Korean Patent Application Nos. 2006-0121624 and 2007-0066125, filed in the Korean Intellectual Property Office on Dec. 4, 2006, and Jul. 2, 2007, respectively, the entire contents of which is incorporated herein by reference.

While the present invention has been described with respect to the particular embodiments, it will be apparent to those skilled in the art that various changes and modifications may be made without departing from the spirit and scope of the invention as defined in the following claims.

1. A biosensor, comprising:
a first conductive semiconductor substrate;
a second conductive doping layer formed on the first conductive semiconductor substrate;
an electrode formed on top of both opposite ends of the doping layer; and
probe molecules immobilized on the doping layer.

2. The biosensor of claim 1, wherein the semiconductor substrate and the doping layer are electrically separated from each other by junction isolation.

3. The biosensor of claim 1, wherein the doping layer is an epitaxial layer.

4. The biosensor of claim 1, wherein the doping layer is an ion implantation layer or a diffusion layer.

5. The biosensor of claim 1, wherein the doping layer is provided in plural, each doping layer having a different probe molecule immobilized thereon.

6. The biosensor of claim 1, wherein the semiconductor substrate and the doping layer are N-type and P-type, or P-type and N-type, respectively, to complement each other.

7. The biosensor of claim 1, further comprising a fluid tube for providing a fluid path in a region of the doping layer on which the probe molecules are immobilized.

8. The biosensor of claim 1, wherein the semiconductor substrate is a bulk silicon substrate.

9. The biosensor of claim 1, wherein the doping layer and the electrode form an ohmic contact.

10. The biosensor of claim 1, wherein the probe molecules are formed of any one selected from the group consisting of antigens, antibodies, DNA, proteins and a combination thereof.

11. A method for manufacturing a biosensor, comprising the steps of:
a) forming a second conductive doping layer on a first conductive semiconductor substrate;
b) forming an electrode on top of both opposite ends of the doping layer; and
c) immobilizing probe molecules on the doping layer.

12. The method of claim 11, wherein the semiconductor substrate and the doping layer are electrically separated from each other by junction isolation.

13. The method of claim 11, wherein the semiconductor substrate and the doping layer are N-type and P-type or P-type and N-type, respectively, to complement each other.

14. The method of claim 11, wherein the doping layer is formed by growing an epitaxial layer on top of the semiconductor layer and doping impurities simultaneously through in-situ method.

15. The method of claim 11, wherein the doping layer is formed on the surface of the semiconductor substrate by using an ion implantation method or a thermal diffusion method.

16. The method of claim 15, further comprising the step of performing thermal treatment after the ion implantation.

17. The method of claim 11, further comprising the step of forming a channel region and a pad region by patterning the doping layer.

18. The method of claim 17, wherein the patterning is performed by any one of photolithography, electron beam lithography, ion-beam lithography, and x-ray lithography.

19. The method of claim 11, further comprising the step of forming a fluid tube for providing a fluid path in a region of the doping layer on which the probe molecules are immobilized.

20. The method of claim 11, wherein the semiconductor substrates is a bulk silicon substrate.

21. The method of claim 11, wherein the doping layer and the electrode form an ohmic contact.

22. The method of claim 11, wherein the probe molecules are formed of any one selected from the group consisting of antigens, antibodies, DNA, proteins, and a combination thereof.
